(19) United States
(12) Patent Application Publication
(10) Pub. No.: US 2026/0173974 A1
(43) Pub. Date: Jun. 18, 2026

(54) COMPOSITE CIRCUIT LAMINATE

(71) Applicants: Innolux Corporation, Miaoli County (TW); nD-HI Technologies Lab, Inc., Taipei City (TW)

(72) Inventors: Ho-Ming Tong, Taipei City (TW); Chih-Chao Chuang, Miaoli County (TW); Shu-Hsien Wu, Miaoli County (TW); Szu-Yen Yu, Miaoli County (TW); Ching-Yu Chu, Miaoli County (TW)

(73) Assignees: Innolux Corporation, Miaoli County (TW); nD-HI Technologies Lab, Inc., Taipei City (TW)

(21) Appl. No.: 19/383,761

(22) Filed: Nov. 10, 2025

Related U.S. Application Data
(60) Provisional application No. 63/734,190, filed on Dec. 16, 2024.

(30) Foreign Application Priority Data
Jul. 14, 2025 (CN) 202510966120.5

(51) Int. Cl. H01L 23/498; B32B 7/12; B32B 15/04

(52) U.S. Cl. CPC H10W 90/401; B32B 7/12; B32B 15/04; H10W 70/685; B32B 2307/304; B32B 2307/7376; B32B 2457/08

(57) ABSTRACT

A composite circuit laminate is provided. The composite circuit laminate includes a first redistribution layer and a second redistribution layer. The first redistribution layer includes at least one first pad and at least one second pad. The second redistribution layer is disposed opposite to the first redistribution layer. The second redistribution layer includes at least one third pad. When the at least one first pad is bonded to the at least one third pad, the at least one first pad is electrically connected to the at least one third pad to transmit electrical signals. The at least one second pad has a functional material.

### CROSS-REFERENCE TO RELATED APPLICATION

This application claims the priority benefit of U.S. provisional application Ser. No. 63/734,190, filed on Dec. 16, 2024, and China application serial no. 202510966120.5, filed on Jul. 14, 2025. The entirety of each of the above-mentioned patent applications is hereby incorporated by reference herein and made a part of this specification.

### BACKGROUND

### Technical Field

The disclosure relates to a composite circuit laminate, and more particularly relates to a composite circuit laminate that may be grounded, dissipate heat, enhance bonding strength, or improve warpage issues through pads having functional materials.

### Description of Related Art

Electronic devices or tiled electronic devices have been widely applied in different fields such as communication, display, automotive, or aerospace. With the vigorous development of electronic devices, there is a trend towards developing thinner and lighter electronic devices. Therefore, the reliability or quality requirements for electronic devices are increasingly higher.

### SUMMARY

The disclosure is directed to a composite circuit laminate that may be grounded, dissipate heat, enhance bonding strength, or improve warpage issues through pads having functional materials.

According to an embodiment of the disclosure, a composite circuit laminate includes a first redistribution layer and a second redistribution layer. The first redistribution layer includes at least one first pad and at least one second pad. The second redistribution layer is disposed opposite to the first redistribution layer. The second redistribution layer includes at least one third pad. When the at least one first pad is bonded to the at least one third pad, the at least one first pad is electrically connected to the at least one third pad to transmit electrical signals. The at least one second pad has a functional material.

### BRIEF DESCRIPTION OF THE DRAWINGS

FIG. 1 is a flowchart of a manufacturing method of an electronic device according to the first embodiment of the disclosure.

FIG. 2 to FIG. 4 are schematic cross-sectional diagrams of a manufacturing method of an electronic device according to the first embodiment of the disclosure.

FIG. 5 is a flowchart of the manufacturing method of the first redistribution layer depicted in FIG. 2.

FIG. 6 is a schematic cross-sectional diagram of the manufacturing method of the first redistribution layer depicted in FIG. 2.

FIG. 7 is a schematic cross-sectional diagram of a composite circuit laminate in an electronic device according to the second embodiment of the disclosure.

FIG. 8 is a schematic cross-sectional diagram of a composite circuit laminate in an electronic device according to the third embodiment of the disclosure.

FIG. 9 is a schematic cross-sectional diagram of a composite circuit laminate in an electronic device according to the fourth embodiment of the disclosure.

FIG. 10 is a schematic cross-sectional diagram of a composite circuit laminate in an electronic device according to the fifth embodiment of the disclosure.

### DESCRIPTION OF THE EMBODIMENTS

The disclosure may be understood by referring to the following detailed description with reference to the accompanying drawings. It is noted that for comprehension of the reader and simplicity of the drawings, in the drawings of the disclosure, only a part of the electronic device is shown, and specific components in the drawings are not necessarily drawn to scale. Moreover, the quantity and the size of each component in the drawings are only schematic and are not intended to limit the scope of the disclosure.

In the following specification and claims, the terms “having”, “including”, and “comprising” etc. are open-ended terms, so they should be interpreted to mean “including but not limited to . . . ”.

It should be understood that when a component or a film layer is described as being “on” or “connected to” another component or film layer, it may be directly on or connected to the another component or film layer, or there is an intervening component or film layer therebetween (i.e., indirect on or indirect connection). Conversely, when a component or film layer is described as being “directly on” or “directly connected to” another component or film layer, there is no intervening component or film layer therebetween.

The terms such as “first”, “second”, “third”, etc. may be used to describe components, but the components should not be limited by these terms. The terms are only intended to distinguish a component from another component in the specification. In the claims, different technical terms may be used, and the order of declaration of the components in the claims might replace these with “first,” “second,” “third,” etc. Accordingly, in the specification, a first component may be a second component in the claims.

In the text, the terms “about”, “around”, “substantially”, and “approximately” usually represent within 10%, or within 5%, or within 3%, or within 2%, or within 1%, or within 0.5% of a given value or range. The quantities given here are approximate quantities, that is, the meaning of “about”, “around”, “substantially”, and “approximately” may still be implied in the case where the description of “about”, “around”, “substantially”, and “approximately” are not specified.

In some embodiments of the disclosure, terms such as “connected” and “interconnected” related to joining and connecting, unless otherwise specified, may mean that two structures are in direct contact, or may also mean that two structures are not in direct contact, and there are other structures disposed between these two structures. Moreover, the terms related to joining and connecting may also include cases where both structures are movable, or both structures are fixed. In addition, the term “coupled” includes any direct and indirect means of electrical connection.

In some embodiments of the disclosure, the area, width, thickness, or height of various components, or the distance or spacing between components, can be measured using an optical microscope (OM), a scanning electron microscope (SEM), a thin film thickness profilometer (α-step), an ellipsometer, or other suitable methods. In detail, according to some embodiments, a scanning electron microscope may be used to obtain a cross-sectional structure image including the elements to be measured, and measure the area, width, thickness or height of each of the elements, or the distance or spacing between the elements.

In the disclosure, the composite circuit laminate may be applied to an electronic device. The electronic device may include a display device (including a transparent display device), a light-emitting device, a backlight device, a virtual reality device, an augmented reality (AR) device, an antenna device, a sensing device, a tiled device, a semiconductor device, or any combination thereof, but not limited thereto. The display device may be a non-self-luminous display or a self-luminous display according to requirements, and may be a color display or a monochrome display according to requirements. The antenna device may be a liquid crystal type antenna device or a non-liquid crystal type antenna device. The sensing device may be a sensing device for sensing capacitance, light, thermal energy, or ultrasonic waves. The tiled device may be a display tiled device or an antenna tiled device, but not limited thereto. The semiconductor device may be a central processing unit (CPU), a graphics processing unit (GPU), a memory, a field programmable gate array (FPGA), a silicon photonic and other higher power ICs, SoCs, and chiplet system-level packages, which is applied to high performance computing (HPC) and data centers, 5G/6G, artificial intelligence, electric vehicles (EV), Internet of Things (IoT), and other new terminal applications arising from the emergence of the metaverse. Electronic units in the electronic device may include passive components and active components, such as capacitors, resistors, inductors, diodes, transistors, etc. The diode may include a light emitting diode (LED) or photodiode. The light emitting diode may include, for example, an organic light emitting diode (OLED), a mini LED, a micro LED, or a quantum dot LED, but not limited thereto. The transistor may include, for example, a top-gate thin film transistor, bottom-gate thin film transistor, or dual-gate thin film transistor, but not limited thereto. The electronic device may also include a fluorescence material, a phosphor material, a quantum dot (QD) material, or other suitable materials according to requirements, but not limited thereto. The electronic device may have a peripheral system such as a driving system, a control system, a light source system, etc. to support display devices, antenna devices, wearable devices (e.g., including augmented reality or virtual reality devices), vehicle-mounted devices (e.g., including automobile windshields), or tiled devices. It should be noted that the electronic device may be any combination of the foregoing, but not limited thereto. The following will illustrate the content of the disclosure using an electronic device as an example, but the disclosure is not limited thereto.

In the disclosure, the features in multiple different embodiments described below may be replaced, combined, and/or mixed to form other embodiments without departing from the spirit of the disclosure. The features of the embodiments may be arbitrarily mixed and combined as long as they do not depart from or conflict with the spirit of the disclosure.

Reference will now be made in detail to the exemplary embodiments of the disclosure, examples of which are illustrated in the accompanying drawings. Whenever possible, the same reference numerals are used to represent the same or similar parts in the accompanying drawings and description.

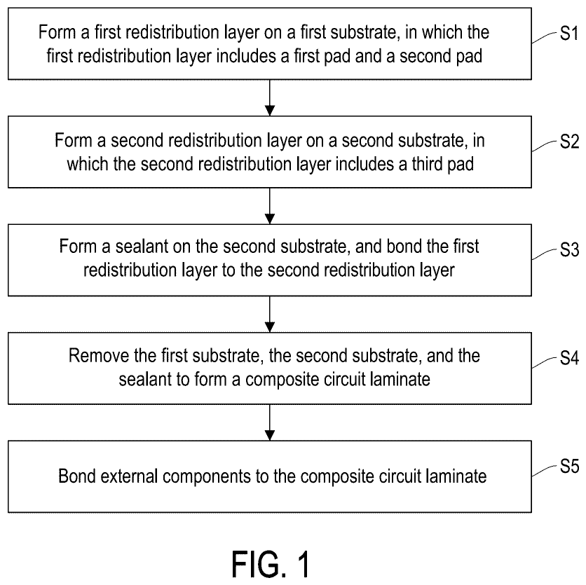

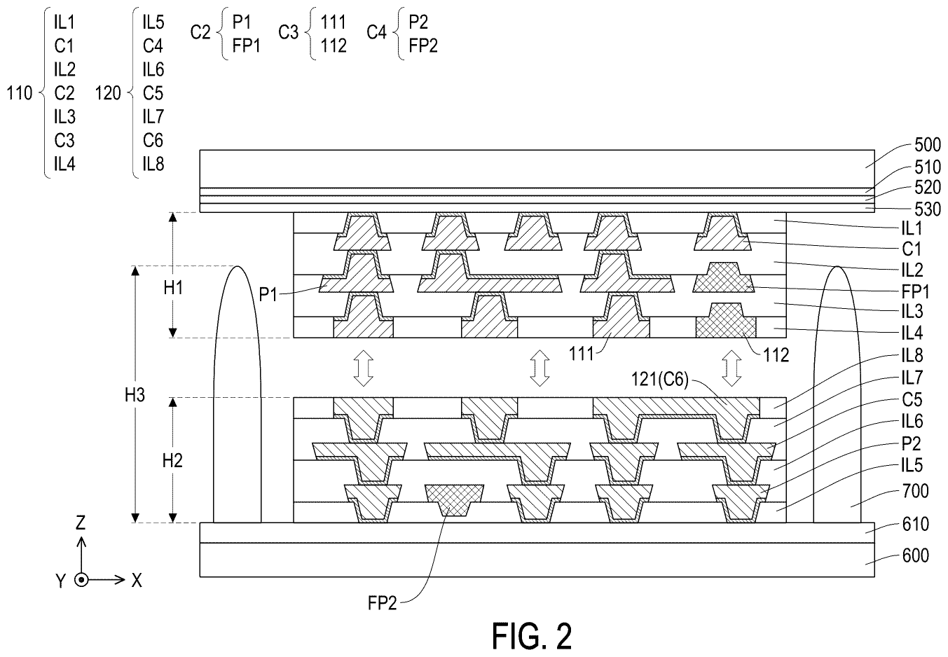

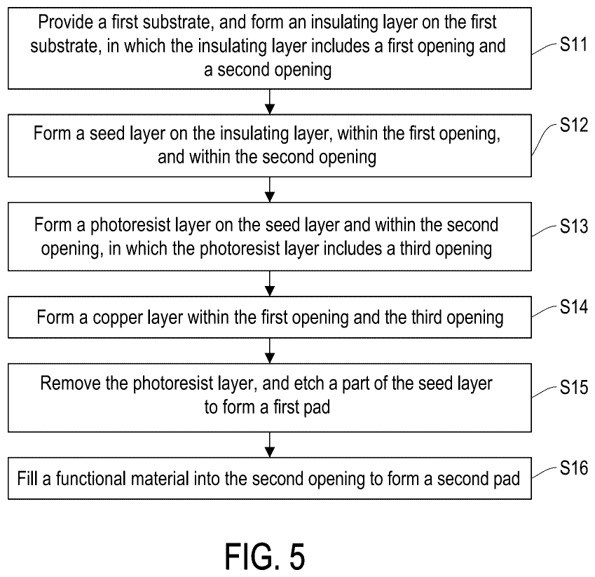

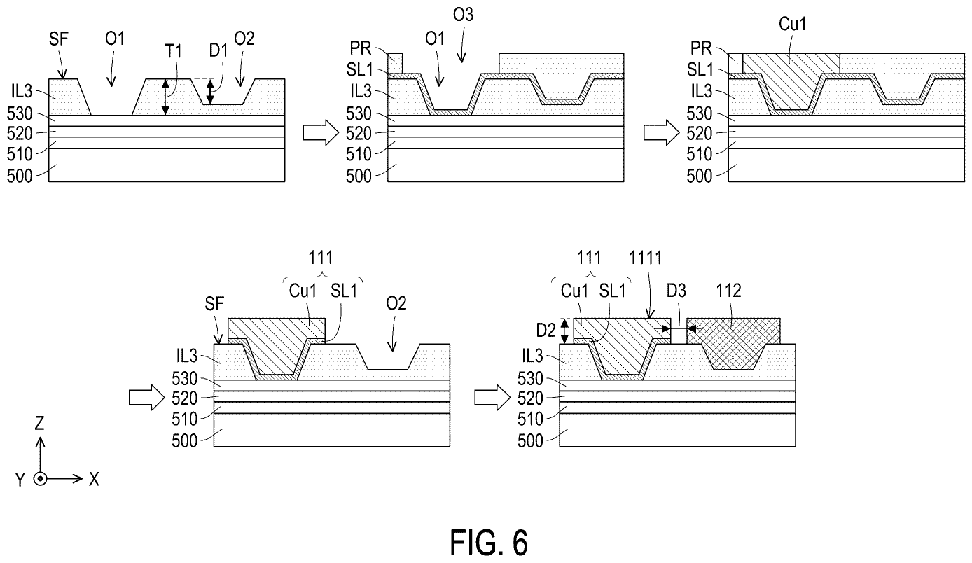

FIG. 1 is a flowchart of a manufacturing method of an electronic device according to the first embodiment of the disclosure. FIG. 2 to FIG. 4 are schematic cross-sectional diagrams of a manufacturing method of an electronic device according to the first embodiment of the disclosure. FIG. 5 is a flowchart of the manufacturing method of the first redistribution layer depicted in FIG. 2. FIG. 6 is a schematic cross-sectional diagram of the manufacturing method of the first redistribution layer depicted in FIG. 2.

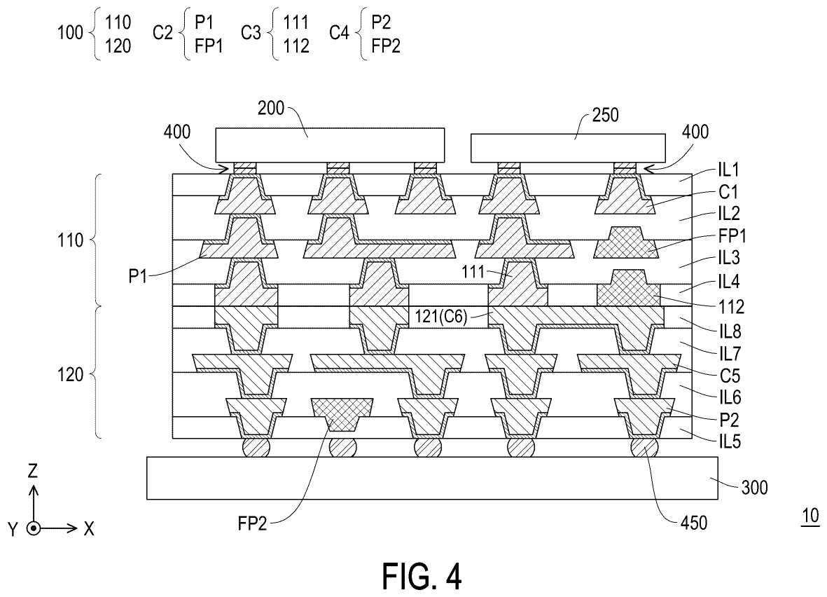

Referring to FIG. 4 first, an electronic device 10 of the embodiment includes a composite circuit laminate 100, a first external component 200, a second external component 250, a circuit board 300, a connector 400, and a connector 450.

Specifically, the first external component 200 and the second external component 250 are disposed on the composite circuit laminate 100 through the connector 400. The composite circuit laminate 100 is disposed on the circuit board 300 through the connector 450. The composite circuit laminate 100 includes a first redistribution layer 110 and a second redistribution layer 120. The first redistribution layer 110 includes at least one first pad 111 and at least one second pad 112. The second redistribution layer 120 is disposed opposite to the first redistribution layer 110. The second redistribution layer 120 includes at least one third pad 121. When the at least one first pad 111 is bonded to the at least one third pad 121, the at least one first pad 111 is electrically connected to the at least one third pad 121 to transmit electrical signals. The at least one second pad 112 has a functional material.

Then, referring to FIG. 1 to FIG. 4 at the same time, the manufacturing method of the electronic device 10 of the embodiment will be illustrated below.

First, referring to FIG. 1 and FIG. 2, step S1 is performed to form the first redistribution layer 110 on a first substrate 500, an anti-warping layer 510, a release layer 520, and a protection layer 530. In detail, the anti-warping layer 510 is disposed on the first substrate 500, the release layer 520 is disposed on the anti-warping layer 510, and the protection layer 530 is disposed on the release layer 520.

In the embodiment, the first substrate 500 may include a rigid substrate, a flexible substrate, or a combination thereof. For example, a material of the first substrate 500 may include glass, quartz, sapphire, ceramic, polycarbonate (PC), polyimide (PI), polyethylene terephthalate (PET), other suitable substrate materials, or a combination thereof, but not limited thereto.

In the embodiment, a thickness of the anti-warping layer 510 is between 0.1 micrometers (μm) to 5 micrometers (μm), and may include polymer-based photosensitive resins, ceramic materials such as silicon nitride, silicon oxide, spin-on glass, phosphosilicate glass (PSG), borosilicate glass (BSG), borophosphosilicate glass (BPSG), etc., but not limited thereto. A formation of the anti-warping layer 510 may be performed through physical vapor deposition (PVD), chemical vapor deposition (CVD), strip coating, or spin coating methods, but not limited thereto. A material of the release layer 520 may include a base selected from organic resins, oxides, or polymer composite materials, and may include a decomposition agent selected from thermosensitive compounds, photoreactive compounds, redox active salts, or moisture-sensitive compounds. Additionally, it may further include selective energy absorption additives, but not limited thereto. A selected material of the release layer 520 may decompose or release gas upon exposure to stimuli such as heat, light, electric field, or chemicals to achieve separation of the attached upper and lower layers. A material of the protection layer 530 may include a thin metal film, but not limited thereto.

The first redistribution layer 110 includes an insulating layer IL1, a first circuit layer C1, an insulating layer IL2, a second circuit layer C2, an insulating layer IL3, a third circuit layer C3, and an insulating layer IL4. The insulating layer IL1 is disposed on the protection layer 530. The first circuit layer C1 is disposed on the insulating layer IL1. The insulating layer IL2 is disposed on the first circuit layer C1. The second circuit layer C2 is disposed on the insulating layer IL2. The insulating layer IL3 is disposed on the second circuit layer C2. The third circuit layer C3 is disposed on the insulating layer IL3. The insulating layer IL4 is disposed on the insulating layer IL3 exposed by the third circuit layer C3. In the embodiment, the first redistribution layer 110 has a height H1, and the height H1 may be the height measured along a direction Z of the first redistribution layer 110.

In the embodiment, the direction X, direction Y, and direction Z are respectively different directions. The direction X is, for example, the extending direction of the first substrate 500 in FIG. 2, and the direction Z is, for example, the normal direction of the first substrate 500 or the normal direction of the composite circuit laminate 100. The direction X may be substantially perpendicular to the direction Z, and the direction X and the direction Z may be substantially perpendicular to direction Y, respectively, but not limited thereto.

The second circuit layer C2 includes a pad P1 and a pad FP1. The pad P1 and the pad FP1 are disposed on the same layer, and the pad P1 and the pad FP1 are separated from each other. The pad P1 may penetrate the insulating layer IL2 to be electrically connected to the first circuit layer C1. The pad FP1 does not penetrate the insulating layer IL2, and the pad FP1 is not electrically connected to the pad P1 and the first circuit layer C1, respectively.

The third circuit layer C3 includes a first pad 111 and a second pad 112. The first pad 111 and the second pad 112 are disposed on the same layer, and the first pad 111 and the second pad 112 are separated from each other. The first pad 111 may penetrate the insulating layer IL3 to be electrically connected to the pad P1 of the second circuit layer C2. The second pad 112 does not penetrate the insulating layer IL3, and the second pad 112 is not electrically connected to the first pad 111 and the pad P1 of the second circuit layer C2, respectively.

In the embodiment, the pad FP1 and the second pad 112 have functional materials, and the functional material may include metal, adhesive material, or invar alloy, but not limited thereto. In an embodiment, when the functional material of the pad FP1 or the second pad 112 includes metal, the pad FP1 or the second pad 112 may be grounded to reduce impedance and avoid noise interference, or may enhance structural support, or adjust structural stress. In an embodiment, when the functional material of the pad FP1 or the second pad 112 is an adhesive material containing a filler, the pad FP1 or the second pad 112 may be used for heat dissipation to improve overheating problems or may adjust the thermal expansion coefficient (CTE). The size of the filler is between 0.1 μm and 100 μm. A material of the filler may include a thermally conductive material (such as graphene, graphite, titanium dioxide (TiO₂), aluminum nitride (AlN), aluminum oxide (Al₂O₃), or ceramic) or material with a low thermal expansion coefficient (such as silicon dioxide (SiO₂)). Meanwhile, the adhesive material filled in the pad FP1 or the second pad 112 may also be used for bonding to enhance the bonding strength when subsequently bonding the first redistribution layer 110 to the second redistribution layer 120, but not limited thereto. In an embodiment, when the functional material of the pad FP1 or the second pad 112 includes invar alloy, the pad FP1 or the second pad 112 may be used for anti-warpage to improve warpage issues, but not limited thereto.

In some embodiments, pads having functional materials may be disposed in each layer or certain layers of circuit layers (including the first circuit layer, second circuit layer, and third circuit layer) within the first redistribution layer as required. Such requirements may include, for example, prediction of warpage degree of layers to be completed, bonding capability or matching of subsequent process materials, or heat dissipation requirements, etc.

In the embodiment, the insulating layer IL1, the insulating layer IL2, the insulating layer IL3, and the insulating layer IL4 may be single-layer structures or multi-layer structures, and may include, for example, organic materials (such as photosensitive dielectric materials), inorganic materials, or a combination thereof, but not limited thereto.

Next, continuing to refer to FIG. 1 and FIG. 2, step S2 is performed to form the second redistribution layer 120 on a second substrate 600 and a release layer 610. In detail, the release layer 610 is disposed on the second substrate 600, and the second redistribution layer 120 is disposed on the release layer 610. In the embodiment, a material of the second substrate 600 may be the same as or similar to the material of the first substrate 500, and a material of the release layer 610 may be the same as or similar to the material of the release layer 520, so it will not be repeated here.

The second redistribution layer 120 includes an insulating layer IL5, a fourth circuit layer C4, an insulating layer IL6, a fifth circuit layer C5, an insulating layer IL7, a sixth circuit layer C6, and an insulating layer IL8. The insulating layer IL5 is disposed on the release layer 610, the fourth circuit layer C4 is disposed on the insulating layer IL5, the insulating layer IL6 is disposed on the fourth circuit layer C4, the fifth circuit layer C5 is disposed on the insulating layer IL6, the insulating layer IL7 is disposed on the fifth circuit layer C5, the sixth circuit layer C6 is disposed on the insulating layer IL7, and the insulating layer IL8 is disposed on the insulating layer IL7 exposed by the sixth circuit layer C6. In the embodiment, the second redistribution layer 120 has a height H2, and the height H2 may be the height measured along the direction Z of the second redistribution layer 120.

The fourth circuit layer C4 includes a pad P2 and a pad FP2. The pad P2 and the pad FP2 are disposed on the same layer, and the pad P2 and the pad FP2 are separated from each other. The pad P2 may penetrate the insulating layer IL5 and the pad P2 may be electrically connected to the fifth circuit layer C5. The pad FP2 does not penetrate the insulating layer IL5, and the pad FP2 is not electrically connected to the pad P2 and the fifth circuit layer C5, respectively.

The sixth circuit layer C6 includes a third pad 121. The third pad 121 may penetrate the insulating layer IL7 to be electrically connected to the fifth circuit layer C5.

In the embodiment, a material of the pad FP2 may be the same as or similar to the material of the pad FP1 or the second pad 112, so it will not be repeated here.

In the embodiment, the insulating layer IL5, the insulating layer IL6, the insulating layer IL7, and the insulating layer IL8 may be single-layer structures or multi-layer structures, and may include, for example, organic materials (such as photosensitive dielectric materials), inorganic materials, or a combination thereof, but not limited thereto.

Next, continuing to refer to FIG. 1 and FIG. 2, step S3 is performed to form a sealant 700 on the second substrate 600 and the release layer 610, and to bond the first redistribution layer 110 to the second redistribution layer 120. In some embodiments, the sealant may also be formed on the first substrate and the protection layer.

In the embodiment, a material of the sealant 700 may include an adhesive material, and the material of the sealant 700 may be adjusted according to requirements (such as heat dissipation, positioning, or support), but not limited thereto. For example, when heat dissipation particles are added, the sealant 700 may have the function of heat dissipation. When the hardness of the adhesive material is adjusted, the sealant 700 may have the function of support.

In the embodiment, for example, an LCD assembly alignment system or other suitable assembly alignment systems may be utilized to align and bond the first redistribution layer 110 and the second redistribution layer 120, but not limited thereto.

In the embodiment, for example, a Cu—Cu hybrid bonding method may be utilized to bond the first pad 111 of the first redistribution layer 110 to the third pad 121 of the second redistribution layer 120, but not limited thereto.

In the embodiment, the sealant 700 has a height H3, and the height H3 may be the height of the sealant 700 measured along the direction Z. In the embodiment, the height H3 of the sealant 700 may be greater than or equal to the height H1 of the first redistribution layer 110 (or the height H2 of the second redistribution layer 120), and the height H3 of the sealant 700 may be less than or equal to the sum of the height H1 of the first redistribution layer 110 and the height H2 of the second redistribution layer 120 (i.e., H1≤H3≤H1+H2, or H2≤H3≤H1+H2), but not limited thereto.

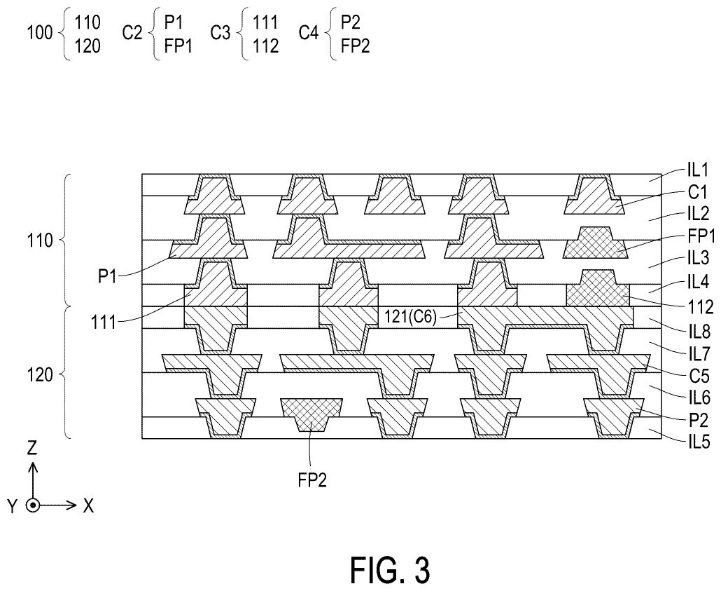

Then, referring to FIG. 1 and FIG. 3, step S4 is performed to remove the first substrate 500, the anti-warping layer 510, the release layer 520, the protection layer 530, the second substrate 600, the release layer 610, and the sealant 700, so as to form the composite circuit laminate 100. In detail, in the composite circuit laminate 100, the first pad 111 of the first redistribution layer 110 may be in contact with and electrically connected to the third pad 121 of the second redistribution layer 120, the second pad 112 of the first redistribution layer 110 may be in contact with another third pad 121 of the second redistribution layer 120, and the second pad 112 is not electrically connected to the second redistribution layer 120, but not limited thereto. In the embodiment, a contour shape of the first pad 111 and a contour shape of the third pad 121 in the composite circuit laminate 100 may be mirror symmetric, but not limited thereto.

In the embodiment, if both the first redistribution layer 110 and the second redistribution layer 120 experience warping in the same direction, by flipping the first redistribution layer 110 upside down and bonding it to the second redistribution layer 120, the warpage issues of the first redistribution layer 110 and the second redistribution layer 120 may be reduced, but not limited thereto.

Then, referring to FIG. 1 and FIG. 4, step S5 is performed to bond external components (including the first external component 200 and the second external component 250) to the composite circuit laminate 100 through the connector 400, and bond the composite circuit laminate 100 to the circuit board 300 through the connector 450, so as to form the electronic device 10. In the embodiment, the connector 400 may be tin-silver alloy or copper-tin alloy, and the connector 450 may be solder balls, but not limited thereto.

Then, referring to FIG. 5 to FIG. 6 at the same time, the following will illustrate the manufacturing method of the first redistribution layer of the embodiment. For clarity of the drawings and convenience of illustration, FIG. 6 omits showing several components in the first redistribution layer 110 (for example, the insulating layer IL1, the first circuit layer C1, the insulating layer IL2, the second circuit layer C2), and uses the first pad 111 and the second pad 112 in the third circuit layer C3 as examples for illustration.

Referring to FIG. 5 and FIG. 6, step S11 is performed to provide the first substrate 500, and sequentially form the anti-warping layer 510, the release layer 520, the protection layer 530, and the insulating layer IL3 on the first substrate 500. In detail, the insulating layer IL3 includes a first opening O1, a second opening O2, and a surface SF facing away from the first substrate 500. The first opening O1 may penetrate the insulating layer IL3 to expose part of the protection layer 530. The second opening O2 does not penetrate the insulating layer IL3, and the second opening O2 may be regarded as a groove. In the embodiment, the first opening O1 and the second opening O2 of the insulating layer IL3 are formed by using, for example, lithography process with half-tone mask or gray-tone mask, but not limited thereto.

In the embodiment, the insulating layer IL3 has a thickness T1, and the second opening O2 has a depth D1. The thickness T1 may be a maximum thickness of the insulating layer IL3 measured along the direction Z, and the depth D1 may be a maximum depth of the second opening O2 measured along the direction Z. In the embodiment, the depth D1 of the second opening O2 may be greater than or equal to 0.1 times the thickness T1 of the insulating layer IL3 and may be less than or equal to the thickness T1 (i.e., 0.1×T1≤D1≤T1). The depth D1 is related to the via filling material. In an embodiment, when the via filling material is a metal material, the interference due to mutual coupling or metal migration between the via filling material and the metal wiring needs to be considered. At this time, the depth D1 of the second opening O2 will be less than the thickness T1 of the insulating layer IL3, but not limited thereto.

Then, step S12 is performed to form a seed layer SL1 on the surface SF of the insulating layer IL3, within the first opening O1, and within the second opening O2. In detail, the seed layer SL1 may contact a part of the protection layer 530 exposed by the first opening O1.

Then, step S13 is performed to form a photoresist layer PR on the seed layer SL1 and within the second opening O2. In detail, the photoresist layer PR includes a third opening O3. The third opening O3 may be connected to the first opening O1 to expose a part of the seed layer SL1. In the direction Z, the third opening O3 may overlap and correspond to the first opening O1.

Then, step S14 is performed to form a copper layer Cu1 within the first opening O1 and the third opening O3. In detail, the copper layer Cu1 is formed by using, for example, electroplating method, but not limited thereto.

Then, step S15 is performed to remove the photoresist layer PR and etch a part of the seed layer SL1 to form the first pad 111. In detail, in the etching step, the seed layer SL1 located on the surface SF of the insulating layer IL3 and within the second opening O2 is etched and removed, and the seed layer SL1 located within the first opening O1 is retained. In the embodiment, the first pad 111 may include the copper layer Cu1 and the seed layer SL1 located within the first opening O1. The first pad 111 has a surface 1111 facing away from the first substrate 500.

Then, step S16 is performed to fill a functional material into the second opening O2 to form the second pad 112. In detail, when the functional material includes metal or invar alloy, for example, the process involves initially filling with powder form, and using a laser locally heating afterwards to form the functional material. When the functional material includes an adhesive material, methods such as one drop filling (ODF) may be adopted for filing the functional material, but not limited thereto. In the embodiment, the depth D1 of the second pad 112 in the insulating layer IL3 may be greater than or equal to 0.1 times the thickness T1 of the insulating layer IL3 and may be less than or equal to the thickness T1 (i.e., 0.1×T1≤D1≤T1). The design trade-off reasons for the depth D1 of the second opening O2 and the thickness T1 of the insulating layer IL3 are as described above, so it will not be repeated here.

In the embodiment, a first distance D2 is between the surface 1111 of first pad 111 and the surface SF of the insulating layer IL3, and a second distance D3 is between the first pad 111 and the second pad 112. The first distance D2 may be a minimum distance measured along the direction Z between the surface 1111 of the first pad 111 and the surface SF of the insulating layer IL3, and the second distance D3 may be a minimum distance measured along the direction X between the first pad 111 and the second pad 112. The second distance D3 is related to the via filling material. In an embodiment, when the via filling material is a metal material, the interference due to mutual coupling or metal migration between the via filling material and the metal wiring needs to be considered. At this time, the second distance D3 may be greater than or equal to 0.6 times the first distance D2 (i.e., 0.6×D2≤D3), but not limited thereto.

Other embodiments will be provided below for description. It should be noted here that the reference numerals and part of contents of the embodiments above remain to be used in the following embodiments, where the same reference numerals are used to denote the same or like elements, and the description of the same technical content is omitted. Reference may be made to the embodiments above for the description of the omitted parts, which will not be repeated in the following embodiments.

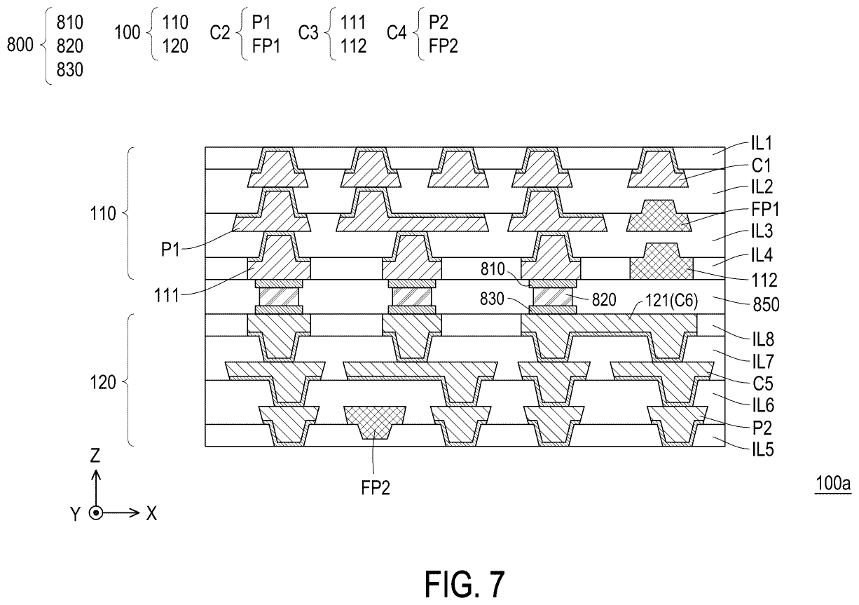

FIG. 7 is a schematic cross-sectional diagram of a composite circuit laminate in an electronic device according to the second embodiment of the disclosure. Referring to FIG. 7 and FIG. 3 at the same time, a composite circuit laminate 100a of the embodiment is similar to the composite circuit laminate 100 depicted in FIG. 3, but the difference between them lies in that the composite circuit laminate 100a of the embodiment further includes a bonding member 800 and an adhesive layer 850.

Specifically, referring to FIG. 7, the bonding member 800 is disposed between the first pad 111 and the third pad 121, and the first pad 111 of the first redistribution layer 110 may be bonded to the third pad 121 of the second redistribution layer 120 through the bonding member 800. The bonding member 800 includes a metal pad 810, a metal pad 820, and a metal pad 830, and the metal pad 820 is disposed between the metal pad 810 and the metal pad 830. In the embodiment, a material of the metal pad 810 and a material of the metal pad 830 may include nickel, and a material of the metal pad 820 may include tin-silver alloy, but not limited thereto.

The first redistribution layer 110 may also be bonded to the second redistribution layer 120 through the adhesive layer 850. In the embodiment, a material of the adhesive layer 850 may include thermoplastic polyimide, epoxy molding compound (EMC), other suitable adhesive materials, or a combination of the foregoing, but not limited thereto.

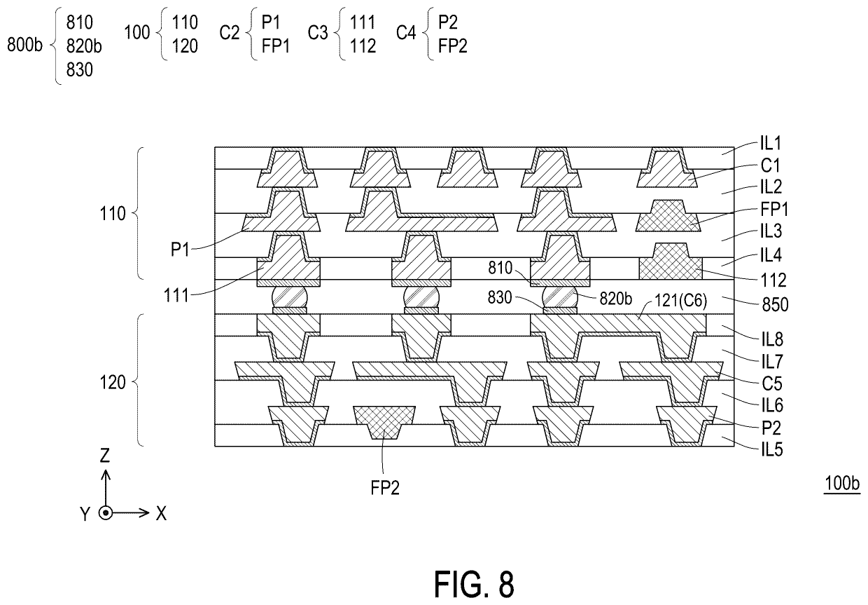

FIG. 8 is a schematic cross-sectional diagram of a composite circuit laminate in an electronic device according to the third embodiment of the disclosure. Referring to FIG. 8 and FIG. 7 at the same time, a composite circuit laminate 100b of the embodiment is similar to the composite circuit laminate 100a depicted in FIG. 7, but the difference between them lies in that in the composite circuit laminate 100b of the embodiment, a bonding member 800b is used to replace the bonding member 800 depicted in FIG. 7.

Specifically, referring to FIG. 8, the bonding member 800b includes a metal pad 810, a solder ball 820b, and a metal pad 830, and the solder ball 820b is disposed between the metal pad 810 and the metal pad 830. In the embodiment, a material of the metal pad 810 and a material of the metal pad 830 may include copper-tin alloy, and a material of the solder ball 820b may include tin, but not limited thereto.

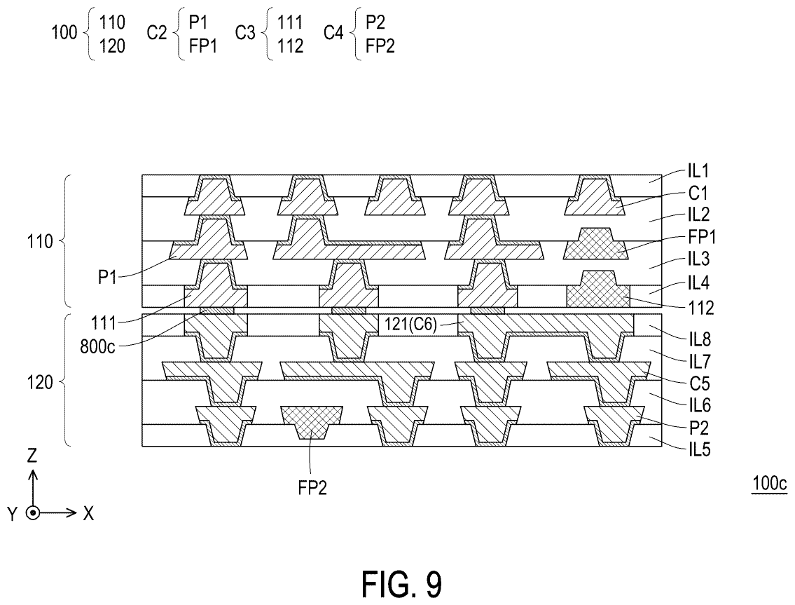

FIG. 9 is a schematic cross-sectional diagram of a composite circuit laminate in an electronic device according to the fourth embodiment of the disclosure. Referring to FIG. 9 and FIG. 7 at the same time, a composite circuit laminate 100c of the embodiment is similar to the composite circuit laminate 100a depicted in FIG. 7, but the difference between them lies in that in the composite circuit laminate 100c of the embodiment, a bonding member 800c is used to replace the bonding member 800 and the adhesive layer 850 depicted in FIG. 7.

Specifically, referring to FIG. 9, the bonding member 800c is disposed between the first pad 111 and the third pad 121, and the first pad 111 of the first redistribution layer 110 may be bonded to the third pad 121 of the second redistribution layer 120 through the bonding member 800c. A material of the bonding member 800c may include nano-twinned copper, but not limited thereto.

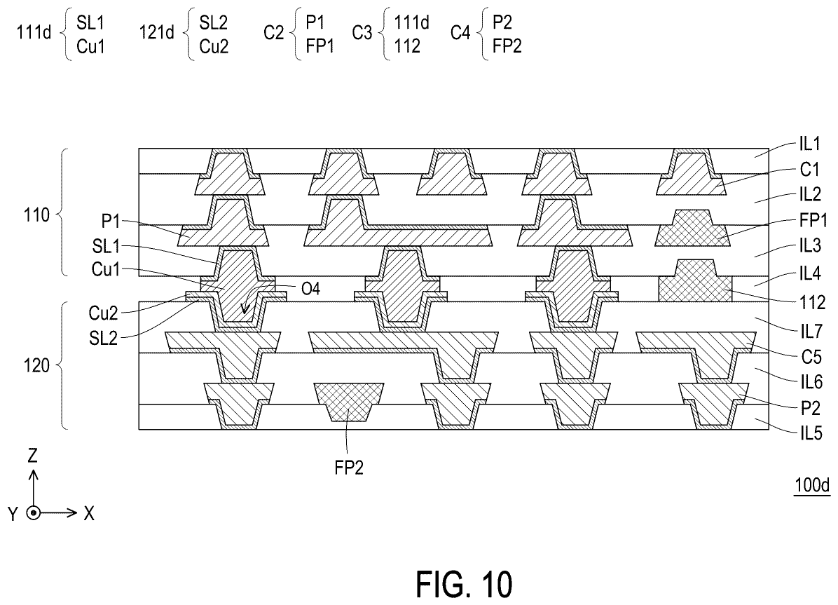

FIG. 10 is a schematic cross-sectional diagram of a composite circuit laminate in an electronic device according to the fifth embodiment of the disclosure. Referring to FIG. 10 and FIG. 3 at the same time, a composite circuit laminate 100d of the embodiment is similar to the composite circuit laminate 100 depicted in FIG. 3, but the difference between them lies in that in the composite circuit laminate 100d of the embodiment, a shape of a first pad 111d is a columnar body, and a shape of a third pad 121d is a groove.

Specifically, referring to FIG. 10, the first pad 111d may include a seed layer SL1 and a copper layer Cu1. The seed layer SL1 and the copper layer Cu1 are sequentially disposed within the first opening O1 of the insulating layer IL3, and the copper layer Cu1 may protrude outside the first opening O1.

The third pad 121d may include a seed layer SL2 and a copper layer Cu2. The seed layer SL2 and the copper layer Cu2 are sequentially disposed within a fourth opening O4 of the insulating layer IL7, and the seed layer SL2 and the copper layer Cu2 do not fill the fourth opening O4 such that a shape of a groove is formed.

When the first pad 111d is bonded to the third pad 121d, the first pad 111d may contact the third pad 121d located within the fourth opening O4, and the first pad 111d may align and engage with the fourth opening O4.

In some embodiments, the shape of the first pad may also be a groove, and the shape of the third pad may also be a columnar body, so that the third pad may align and engage with the first opening.

In summary, in the composite circuit laminate of an embodiment of the disclosure, the manufacturing yield may be improved by first separately manufacturing the first redistribution layer and the second redistribution layer with different line width/line spacing (L/S), and then bonding the first redistribution layer and the second redistribution layer with two different line width/line spacing (L/S) using the bonding method of the disclosure. In addition, compared to the conventional manufacturing method which involves stacking one insulating layer with one copper layer, the disclosure not only achieves a higher yield, but also allows the second pad of the first redistribution layer to be grounded, dissipate heat, enhance bonding strength, or improve warpage issues in the composite circuit laminate by having a functional material (including metal, adhesive material, or invar alloy).

Finally, it should be noted that the above embodiments are only used to illustrate the technical solutions of the disclosure, and not to limit them. Although the disclosure has been described in detail with reference to the foregoing embodiments, those of ordinary skill in the art should understand that: The technical solutions described in the foregoing embodiments can still be modified, or some or all of the technical features thereof can be equivalently replaced; and these modifications or replacements do not make the essence of the corresponding technical solutions deviate from the scope of the technical solutions of the embodiments of the disclosure.

What is claimed is:

1. A composite circuit laminate, comprising:
a first redistribution layer, comprising at least one first pad and at least one second pad; and
a second redistribution layer, disposed opposite to the first redistribution layer, and comprising at least one third pad;
wherein when the at least one first pad is bonded to the at least one third pad, the at least one first pad is electrically connected to the at least one third pad to transmit electrical signals,
wherein the at least one second pad has a functional material.

2. The composite circuit laminate according to claim 1, wherein the functional material comprises metal, an adhesive material, or invar alloy.

3. The composite circuit laminate according to claim 1, wherein the at least one first pad is bonded to the at least one third pad through a bonding member.

4. The composite circuit laminate according to claim 3, wherein a material of the bonding member comprises nickel, tin, tin-silver alloy, or copper-tin alloy.

5. The composite circuit laminate according to claim 3, wherein the bonding member comprises a first metal pad, a second metal pad, and a third metal pad, the second metal pad is disposed between the first metal pad and the third metal pad, and a material of the second metal pad is different from a material of the first metal pad and a material of the third metal pad.

6. The composite circuit laminate according to claim 5, wherein the material of the first metal pad is the same as the material of the third metal pad.

7. The composite circuit laminate according to claim 1, wherein one of the at least one first pad and the at least one third pad is a columnar body, the other one of the at least one first pad and the at least one third pad is a groove, and the columnar body corresponds to the groove.

8. The composite circuit laminate according to claim 1, wherein the first redistribution layer further comprises:
an insulating layer, wherein the at least one first pad penetrates the insulating layer, and the at least one second pad does not penetrate the insulating layer.

9. The composite circuit laminate according to claim 8, wherein there is a first distance between a surface of the at least one first pad and a surface of the insulating layer, there is a second distance between the at least one first pad and the at least one second pad, and the second distance is greater than or equal to 0.6 times the first distance.

10. The composite circuit laminate according to claim 8, wherein the insulating layer has at least one opening, the at least one opening does not penetrate the insulating layer, and the at least one second pad is disposed on the insulating layer and within the at least one opening.

11. The composite circuit laminate according to claim 10, wherein a depth of the at least one opening is greater than or equal to 0.1 times a thickness of the insulating layer and less than or equal to the thickness.

12. The composite circuit laminate according to claim 1, wherein the at least one first pad and the at least one second pad are separated from each other.

13. The composite circuit laminate according to claim 1, wherein the at least one first pad is not electrically connected to the at least one second pad.

14. The composite circuit laminate according to claim 1, wherein the at least one second pad is not electrically connected to the second redistribution layer.

15. The composite circuit laminate according to claim 1, wherein a contour shape of the at least one first pad and a contour shape of the at least one third pad are mirror symmetric.

16. The composite circuit laminate according to claim 1, wherein the first redistribution layer comprises:
a first insulating layer;
a first circuit layer, disposed on the first insulating layer;
a second insulating layer, disposed on the first circuit layer;
a second circuit layer, disposed on the second insulating layer, and comprising at least one fourth pad and at least one fifth pad;
a third insulating layer, disposed on the second circuit layer; and
a third circuit layer, disposed on the third insulating layer, and comprising the at least one first pad and the at least one second pad,
wherein the at least one first pad is electrically connected to the second circuit layer, and the at least one second pad is not electrically connected to the second circuit layer.

17. The composite circuit laminate according to claim 16, wherein the at least one first pad penetrates the third insulating layer, and the at least one second pad does not penetrate the third insulating layer.

18. The composite circuit laminate according to claim 16, wherein the at least one fifth pad has a functional material.

19. The composite circuit laminate according to claim 16, wherein the at least one fourth pad and the at least one fifth pad are separated from each other.

20. The composite circuit laminate according to claim 16, wherein the at least one fourth pad is not electrically connected to the at least one fifth pad.
